(19) United States
(12) Patent Application Publication
(10) Pub. No.: US 2013/0200377 A1
(43) Pub. Date: Aug. 8, 2013

(54) THIN FILM TRANSISTOR ARRAY SUBSTRATE AND METHOD FOR MANUFACTURING THE SAME

(71) Applicants: Pei Jia, Shenzhen (CN); Liu-yang Yang, Shenzhen (CN)

(72) Inventors: Pei Jia, Shenzhen (CN); Liu-yang Yang, Shenzhen (CN)

(73) Assignee: Shenzhen China Star Optoelectronics Technology Co. Ltd, Shanghai (CN)

(21) Appl. No.: 13/391,384

(22) PCT Filed: Feb. 7, 2012
(86) PCT No.: PCT/CN2012/070940

§ 371 Date: Feb. 20, 2012

(30) Foreign Application Priority Data
Feb. 6, 2012 (CN) 201210025352.3

(51) Int. Cl. H01L 21/336; H01L 27/12; H01L 29/786

(52) U.S. Cl. 257/59; 438/158; 257/72; 257/E27.111; 257/E29.273; 257/E21.411

(57) ABSTRACT

The present invention provides a thin film transistor (TFT) array substrate and a method for manufacturing the same. After depositing a first metal layer on a substrate, a first mask is utilized to form gate electrodes. After depositing a gate insulating layer and a semiconductor layer on the substrate, a second mask is utilized to pattern the semiconductor layer, so as to keep portions of the semiconductor layer above the gate electrodes. After depositing a transparent and electrically conductive layer and a second metal layer on the substrate, a multi tone mask is utilized to form source electrodes, drain electrodes, pixel electrodes and common electrodes. The present invention can simplify the manufacturing process thereof.

### FIELD OF THE INVENTION

The present invention relates to a field of a manufacturing technology for liquid crystal displays (LCDs), and more particularly to a thin film transistor (TFT) array substrate and a method for manufacturing the same.

### BACKGROUND OF THE INVENTION

In accordance with a development of LCDs, a high display performance of the LCDs is required. For example, more and more in-plane switching mode (IPS) mode LCDs are applicable to the field of the liquid crystal display technology.

In a process for fabricating the TFT array substrate of the LCDs, masks are required to execute photolithography processes. However, the masks for photolithography are very expensive. The more the number of the masks is, the higher the cost for fabricating the TFT is. Furthermore, more masks will result in longer process time and more complicated process.

Similarly, in the conventional technology, it is more complicated to fabricate the TFT array substrate of the IPS mode LCDs by using the masks (such as four masks), resulting in more difficulty and higher cost for manufacturing the LCDs.

As a result, it is necessary to provide a TFT array substrate and a method for manufacturing the same to solve the problems existing in the conventional technologies, as described above.

### SUMMARY OF THE INVENTION

An object of the present invention is to provide a method for manufacturing a TFT array substrate, so as to solve a problem that the process of manufacturing a TFT array substrate of an IPS mode LCD by using numerous masks is too complicated, resulting in more difficulty and higher cost for manufacturing the LCD.

For solving the above-mentioned problem, the present invention provides a method for manufacturing a TFT array substrate, comprising the following steps: providing a substrate; sputtering a first metal layer on the substrate and utilizing a first mask to pattern the first metal layer, so as to form gate electrodes; depositing a gate insulating layer and a semiconductor layer on the substrate in sequence, and utilizing a second mask to pattern the semiconductor layer, so as to keep portions of the semiconductor layer above the gate electrodes; depositing a transparent and electrically conductive layer and a second metal layer on the substrate in sequence, and utilizing a multi tone mask to pattern the transparent and electrically conductive layer and the second metal layer, so as to form source electrodes and drain electrodes by patterning the transparent and electrically conductive layer and the second metal layer, and to form pixel electrodes and common electrodes by patterning the transparent and electrically conductive layer on the gate insulating layer; and depositing a planarization layer on the pixel electrodes, the common electrodes, and the source electrodes, the drain electrodes and the semiconductor layer of TFTs, wherein the planarization layer is made of a transparent insulating material.

In the method for manufacturing the TFT array substrate of the present invention, the multi tone mask is a gray tone mask (GTM), a stacked layer mask (SLM) or a half tone mask (HTM).

In the method for manufacturing the TFT array substrate of the present invention, the gate insulating layer and the semiconductor layer are deposited by using a chemical vapor deposition method.

In the method for manufacturing the TFT array substrate of the present invention, the transparent and electrically conductive layer and the second metal layer are deposited in sequence by sputtering.

In the method for manufacturing the TFT array substrate of the present invention, the first metal layer is a combination of a first aluminum metal layer and a first molybdenum metal layer, and the second metal layer is a combination of a second molybdenum metal layer, a second aluminum metal layer and a third molybdenum metal layer.

In the method for manufacturing the TFT array substrate of the present invention, during the process of utilizing the first mask to pattern the first metal layer for forming the gate electrodes, the first metal layer is etched by using a mixed solution of nitric acid, phosphoric acid and acetic acid.

In the method for manufacturing the TFT array substrate of the present invention, during the process of utilizing the multi tone mask to pattern the transparent and electrically conductive layer and the second metal layer for forming the source electrodes and the drain electrodes, the second metal layer is etched by using a mixed solution of nitric acid, phosphoric acid and acetic acid, and the transparent and electrically conductive layer is etched by a reactive ion etching (RIE), and during the process of utilizing the multi tone mask to pattern the transparent and electrically conductive layer for forming the pixel electrodes and the common electrodes, the transparent and electrically conductive layer is etched by RIE.

Another object of the present invention is to provide a method for manufacturing a TFT array substrate, so as to solve a problem that the process of manufacturing a TFT array substrate of an IPS mode LCD by using numerous masks is too complicated, resulting in more difficulty and higher cost for manufacturing the LCD.

For solving the above-mentioned problem, the present invention provides a method for manufacturing a TFT array substrate, comprising the following steps: providing a substrate; depositing a first metal layer on the substrate and utilizing a first mask to pattern the first metal layer, so as to form gate electrodes; depositing a gate insulating layer and a semiconductor layer on the substrate in sequence, and utilizing a second mask to pattern the semiconductor layer, so as to keep portions of the semiconductor layer above the gate electrodes; and depositing a transparent and electrically conductive layer and a second metal layer on the substrate in sequence, and utilizing a multi tone mask to pattern the transparent and electrically conductive layer and the second metal layer, so as to form source electrodes and drain electrodes by patterning the transparent and electrically conductive layer and the second metal layer, and to form pixel electrodes and common electrodes by patterning the transparent and electrically conductive layer on the gate insulating layer.

In the method for manufacturing the TFT array substrate of the present invention, after forming the source electrodes, the drain electrodes, the pixel electrodes and the common electrodes, the method further comprises the following step: depositing a planarization layer on the pixel electrodes, the common electrodes, and the source electrodes, the drain electrodes and the semiconductor layer of TFTs, wherein the planarization layer is made of a transparent insulating material.

In the method for manufacturing the TFT array substrate of the present invention, the multi tone mask is a gray tone mask (GTM), a stacked layer mask (SLM) or a half tone mask (HTM).

In the method for manufacturing the TFT array substrate of the present invention, the first metal layer is disposed by sputtering.

In the method for manufacturing the TFT array substrate of the present invention, the gate insulating layer and the semiconductor layer are deposited by using a chemical vapor deposition method.

In the method for manufacturing the TFT array substrate of the present invention, the transparent and electrically conductive layer and the second metal layer are deposited in sequence by sputtering.

In the method for manufacturing the TFT array substrate of the present invention, the first metal layer is a combination of a first aluminum metal layer and a first molybdenum metal layer, and the second metal layer is a combination of a second molybdenum metal layer, a second aluminum metal layer and a third molybdenum metal layer

In the method for manufacturing the TFT array substrate of the present invention, during the process of utilizing the first mask to pattern the first metal layer for forming the gate electrodes, the first metal layer is etched by using a mixed solution of nitric acid, phosphoric acid and acetic acid.

In the method for manufacturing the TFT array substrate of the present invention, during the process of utilizing the multi tone mask to pattern the transparent and electrically conductive layer and the second metal layer for forming the source electrodes and the drain electrodes, the second metal layer is etched by using a mixed solution of nitric acid, phosphoric acid and acetic acid, and the transparent and electrically conductive layer is etched by a reactive ion etching (RIE), and during the process of utilizing the multi tone mask to pattern the transparent and electrically conductive layer for forming the pixel electrodes and the common electrodes, the transparent and electrically conductive layer is etched by RIE.

Still another object of the present invention is to provide a TFT array substrate, so as to solve a problem that the process of manufacturing a TFT array substrate of an IPS mode LCD by using numerous masks is too complicated, resulting in more difficulty and higher cost for manufacturing the LCD.

For solving the above-mentioned problem, the present invention provides a TFT array substrate, comprising: a substrate; a plurality of TFTs disposed on the substrate, wherein each of the TFTs comprises a gate electrode, a gate insulating layer, a semiconductor layer, a source electrode and a drain electrode, and the semiconductor layer, the source electrode and the drain electrode are formed on the substrate in sequence, and the source electrode and the drain electrode are formed by patterning a transparent and electrically conductive layer and a metal layer; a plurality of pixel electrodes formed on the gate insulating layer and connected to the drain electrodes of the TFTs; and a plurality of common electrodes formed on the gate insulating layer, wherein the pixel electrodes and the common electrodes are arranged in an alternating manner.

In the TFT array substrate of the present invention, the first metal layer is a combination of a first aluminum metal layer and a first molybdenum metal layer, and the second metal layer is a combination of a second molybdenum metal layer, a second aluminum metal layer and a third molybdenum metal layer.

Compared with the conventional technology, in the present invention, the first mask is utilized to form the gate electrodes after depositing the first metal layer on the substrate, and a second mask process is performed after depositing the gate insulating layer and the semiconductor layer on the substrate, and the multi tone mask is utilized to form source electrodes, drain electrodes, pixel electrodes and common electrodes after depositing the transparent and electrically conductive layer and the second metal layer on the substrate, thereby forming the TFT array substrate of the IPS mode LCD apparatus. Obviously, the present invention can use only three masks to manufacture the TFT array substrate of an IPS mode LCD apparatus for reducing an amount of the required masks in the fabrication process, hence reducing the cost and time of the fabrication process, and improving a production capacity of the LCD apparatus.

The structure and the technical means adopted by the present invention to achieve the above and other objects can be best understood by referring to the following detailed description of the preferred embodiments and the accompanying drawings.

### DESCRIPTION OF THE DRAWINGS

FIG. 1 is a cross-sectional view showing a display panel and a backlight module according to a preferred embodiment of the present invention; and

FIGS. 2A-2C are schematic flow diagrams showing a process for manufacturing a TFT array substrate according to the preferred embodiment of the present invention.

### DETAILED DESCRIPTION OF THE PREFERRED EMBODIMENTS

The following embodiments are referring to the accompanying drawings for exemplifying specific performable embodiments of the present invention. Furthermore, directional terms described by the present invention, such as upper, lower, front, back, left, right, inner, outer, side and etc., are only directions by referring to the accompanying drawings, and thus the used directional terms are used to describe and understand the present invention, but the present invention is not limited thereto.

In the drawings, structure-like elements are labeled with like reference numerals.

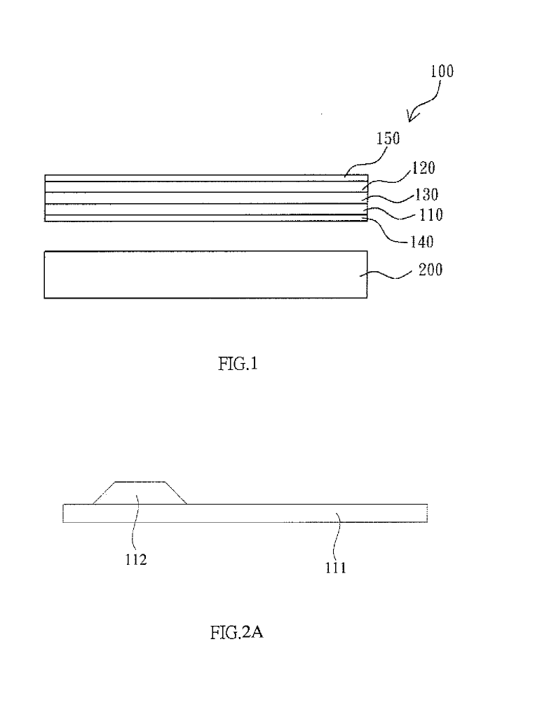

Referring to FIG. 1, a cross-sectional view showing a display panel and a backlight module according to an embodiment of the present invention is illustrated. The method of the present embodiment for manufacturing a TFT array substrate can be applicable to the fabrication of the display panel 100, such as a liquid crystal display panel. When utilizing the display panel 100 of the present embodiment to fabricate a display apparatus, the display panel 100 may be disposed on the backlight module 200, thereby forming a liquid crystal display apparatus. The display panel 100 may comprise a first substrate 110, a second substrate 120, a liquid crystal layer 130, a first polarizer 140 and a second polarizer 150. The first substrate 110 and the second substrate 120 may be realized as glass substrates or flexible plastic substrates. In this embodiment, the first substrate 110 may be, for example, a TFT array substrate, and the second substrate 120 may be, for example, a color filter (CF) substrate. It notes that the CF and the TFT array may also be disposed on the same substrate in other embodiments.

Referring to FIG. 1 again, the liquid crystal layer 130 is formed between the first substrate 110 and the second substrate 120. The first polarizer 140 is disposed on one side of the first substrate 110 and opposite to the liquid crystal layer 130 (as a light-incident side). The second polarizer 150 is disposed on one side of the second substrate 120 and opposite to the liquid crystal layer 130 (as a light-emitting side).

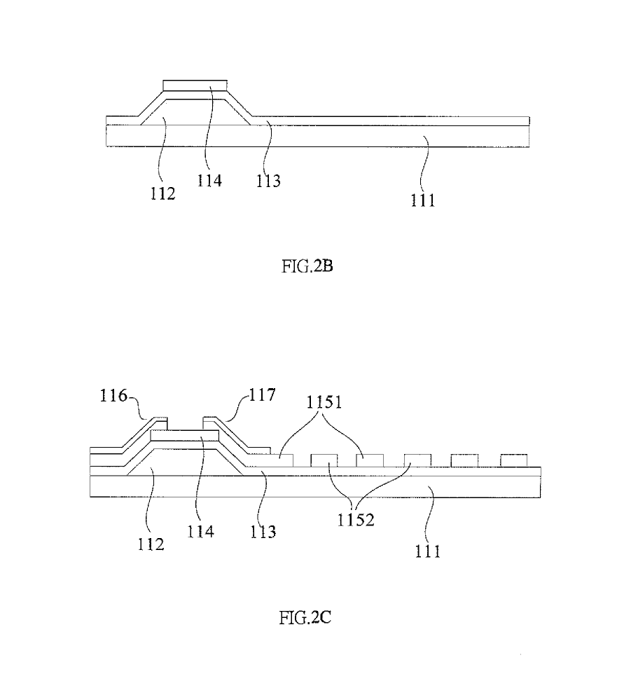

Referring to FIG. 2A through FIG. 2C, schematic flow diagrams showing a process for manufacturing a TFT array substrate according to a preferred embodiment of the present invention are illustrated.

In FIG. 2A, a substrate 111 is provided, and a first metal layer is deposited on the substrate 111. A first mask is utilized to etch the first metal layer, so as to pattern the first metal layer and form gate electrodes 112, as shown in FIG. 2A.

In this case, the first metal layer is preferably a combination of a first aluminum metal layer and a first molybdenum metal layer, and certainly, other materials are also allowable, such as Al, Ag, Cu, Mo, Cr, W, Ta, Ti, metal nitride or any alloys thereof. Furthermore, the first metal layer of the gate electrodes 112 may be a multi-layer structure with heat-resistant film and lower resistance film.

In practice, the first metal layer is preferably formed on the substrate 111 by sputtering. Subsequently, the first metal layer is patterned to form the gate electrodes 112 by a photolithography process and an etching process of a first mask process. In this case, during the process of utilizing the first mask to pattern the first metal layer for forming the gate electrodes 112, the first metal layer is preferably etched by using a mixed solution of nitric acid, phosphoric acid and acetic acid.

Subsequently, referring to FIG. 2B again, a gate insulating layer 113 and a semiconductor layer 114 are deposited on the substrate 111 in sequence, and a second mask is utilized to pattern the semiconductor layer 114, so as to keep portions of the semiconductor layer 114 above the gate electrodes 112 as shown in FIG. 2B.

In the present invention, the gate insulating layer 113 and the semiconductor layer 114 are preferably deposited by using a plasma enhanced chemical vapor deposition (PECVD) method. Certainly, the gate insulating layer 1113 and the semiconductor layer 114 may be deposited by using other methods, and the similarities are not mentioned for simplification.

The material of the gate insulating layer 113 may be silicon nitride (SiNₓ) or silicon oxide (SiOₓ). The semiconductor layer 114 is preferably made of polycrystalline silicon. In this embodiment, for forming the semiconductor layer 114, an amorphous silicon (a-Si) layer can be first deposited, and then a rapid thermal annealing step is performed to the a-Si layer, thereby allowing the a-Si layer to recrystallize into a polycrystalline silicon layer.

Subsequently, referring to FIG. 2C again, a transparent and electrically conductive layer and a second metal layer are deposited on the substrate 111 in sequence by sputtering, wherein the thickness of the transparent and electrically conductive layer is preferably equal to or less than 100 μm. A multi tone mask is utilized to pattern the transparent and electrically conductive layer and the second metal layer, so as to form source electrodes 116 and drain electrodes 117 by patterning the transparent and electrically conductive layer and the second metal layer, and to form pixel electrodes 1151 and common electrodes 1152 by patterning the transparent and electrically conductive layer on the gate insulating layer.

The transparent and electrically conductive layer is made of a transparent and electrically conductive material, such as ITO, TO, IZO and ITZO.

Preferably, the second metal layer is a combination of a second molybdenum metal layer, a second aluminum metal layer and a third molybdenum metal layer, and certainly, other materials are also allowable, such as Al, Ag, Cu, Mo, Cr, W, Ta, Ti, metal nitride or any alloys thereof. Furthermore, the second metal layer may be a multi-layer structure with heat-resistant film and lower resistance film.

In practice, the multi tone mask may be a gray tone mask (GTM), a stacked layer mask (SLM) or a half tone mask (HTM). The multi tone mask can include partial exposure regions, non-exposure regions and full exposure regions so as to pattern the transparent and electrically conductive layer and the second metal layer for forming the source electrodes 116 and the drain electrodes 117 and forming the pixel electrodes 1151 and the common electrodes 1152, wherein the pixel electrodes 1151 are connected to the drain electrodes 117.

In this case, during the process of utilizing the multi tone mask to pattern the transparent and electrically conductive layer and the second metal layer for forming the source electrodes 116 and the drain electrodes 117, the second metal layer is preferably etched by using a mixed solution of nitric acid, phosphoric acid and acetic acid, and the transparent and electrically conductive layer is preferably etched by a dry etching, such as reactive ion etching (RIE). During the process of utilizing the multi tone mask to pattern the transparent and electrically conductive layer for forming the pixel electrodes 1151 and the common electrodes 1152, the transparent and electrically conductive layer is preferably etched by a dry etching, such as RIE.

In one embodiment, after forming the structure as shown in FIG. 2C, a planarization layer (not shown) can be deposited on the pixel electrodes 1151, the common electrodes 1152, and the source electrodes 116, the drain electrodes 117 and the semiconductor layer 114 of TFTs for planarization and protecting devices. Preferably, the planarization layer is made of a transparent insulating material. Certainly, other materials are also allowable, and the similarities are not mentioned for simplification.

The present invention further provides a TFT array substrate. The TFT array substrate comprises the substrate 111 and the plurality of TFTs disposed thereon.

Each of the TFTs comprises the gate electrode 112, the gate insulating layer 113, the semiconductor layer 114, the source electrode 116 and the drain electrode 117. The gate electrode 112, the gate insulating layer 113 and the semiconductor layer 114 are formed on the substrate 111 in sequence. The source electrode 116 and the drain electrode 117 are formed on the semiconductor layer 114 by patterning the transparent and electrically conductive layer and the second metal layer thereon.

The TFT array substrate further comprises the plurality pixel electrodes 1151 and the plurality common electrodes 1152. The pixel electrodes 1151 and the common electrodes 1152 are arranged in an alternating manner by patterning the transparent and electrically conductive layer on the gate insulating layer 113, wherein the pixel electrodes 1151 are connected to the drain electrodes 117.

As described above, the methods of the present invention for manufacturing the TFT array substrate and the display panel can use only three masks to manufacture the TFT array substrate of an IPS mode LCD apparatus for reducing an amount of the required masks in the fabrication process, hence reducing the cost and time of the fabrication process.

The present invention has been described with a preferred embodiment thereof and it is understood that many changes and modifications to the described embodiment can be carried out without departing from the scope and the spirit of the invention that is intended to be limited only by the appended claims.

1. A method for manufacturing a thin film transistor (TFT) array substrate, comprising the following steps:
providing a substrate;
sputtering a first metal layer on the substrate and utilizing a first mask to pattern the first metal layer, so as to form gate electrodes;
depositing a gate insulating layer and a semiconductor layer on the substrate in sequence, and utilizing a second mask to pattern the semiconductor layer, so as to keep portions of the semiconductor layer above the gate electrodes;
depositing a transparent and electrically conductive layer and a second metal layer on the substrate in sequence, and utilizing a multi tone mask to pattern the transparent and electrically conductive layer and the second metal layer, so as to form source electrodes and drain electrodes by patterning the transparent and electrically conductive layer and the second metal layer, and to form pixel electrodes and common electrodes by patterning the transparent and electrically conductive layer on the gate insulating layer; and
depositing a planarization layer on the pixel electrodes, the common electrodes, and the source electrodes, the drain electrodes and the semiconductor layer of TFTs, wherein the planarization layer is made of a transparent insulating material.

2. The method for manufacturing the TFT array substrate according to claim 1, wherein the multi tone mask is a gray tone mask (GTM), a stacked layer mask (SLM) or a half tone mask (HTM).

3. The method for manufacturing the TFT array substrate according to claim 1, wherein the gate insulating layer and the semiconductor layer are deposited by using a chemical vapor deposition method.

4. The method for manufacturing the TFT array substrate according to claim 1, wherein the transparent and electrically conductive layer and the second metal layer are deposited in sequence by sputtering.

5. The method for manufacturing the TFT array substrate according to claim 1, wherein the first metal layer is a combination of a first aluminum metal layer and a first molybdenum metal layer, and the second metal layer is a combination of a second molybdenum metal layer, a second aluminum metal layer and a third molybdenum metal layer.

6. The method for manufacturing the TFT array substrate according to claim 1, wherein, during the process of utilizing the first mask to pattern the first metal layer for forming the gate electrodes, the first metal layer is etched by using a mixed solution of nitric acid, phosphoric acid and acetic acid.

7. The method for manufacturing the TFT array substrate according to claim 1, wherein, during the process of utilizing the multi tone mask to pattern the transparent and electrically conductive layer and the second metal layer for forming the source electrodes and the drain electrodes, the second metal layer is etched by using a mixed solution of nitric acid, phosphoric acid and acetic acid, and the transparent and electrically conductive layer is etched by a reactive ion etching (RIE), and during the process of utilizing the multi tone mask to pattern the transparent and electrically conductive layer for forming the pixel electrodes and the common electrodes, the transparent and electrically conductive layer is etched by RIE.

8. A method for manufacturing a TFT array substrate, comprising the following steps:
providing a substrate;
depositing a first metal layer on the substrate and utilizing a first mask to pattern the first metal layer, so as to form gate electrodes;
depositing a gate insulating layer and a semiconductor layer on the substrate in sequence, and utilizing a second mask to pattern the semiconductor layer, so as to keep portions of the semiconductor layer above the gate electrodes; and
depositing a transparent and electrically conductive layer and a second metal layer on the substrate in sequence, and utilizing a multi tone mask to pattern the transparent and electrically conductive layer and the second metal layer, so as to form source electrodes and drain electrodes by patterning the transparent and electrically conductive layer and the second metal layer, and to form pixel electrodes and common electrodes by patterning the transparent and electrically conductive layer on the gate insulating layer.

9. The method for manufacturing the TFT array substrate according to claim 1, wherein, after forming the source electrodes, the drain electrodes, the pixel electrodes and the common electrodes, the method further comprises the following step:
depositing a planarization layer on the pixel electrodes, the common electrodes, and the source electrodes, the drain electrodes and the semiconductor layer of TFTs, wherein the planarization layer is made of a transparent insulating material.

10. The method for manufacturing the TFT array substrate according to claim 1, wherein the multi tone mask is a gray tone mask (GTM), a stacked layer mask (SLM) or a half tone mask (HTM).

11. The method for manufacturing the TFT array substrate according to claim 1, wherein the first metal layer is disposed by sputtering.

12. The method for manufacturing the TFT array substrate according to claim 1, wherein the gate insulating layer and the semiconductor layer are deposited by using a chemical vapor deposition method.

13. The method for manufacturing the TFT array substrate according to claim 1, wherein the transparent and electrically conductive layer and the second metal layer are deposited in sequence by sputtering.

14. The method for manufacturing the TFT array substrate according to claim 1, wherein the first metal layer is a combination of a first aluminum metal layer and a first molybdenum metal layer, and the second metal layer is a combination of a second molybdenum metal layer, a second aluminum metal layer and a third molybdenum metal layer.

15. The method for manufacturing the TFT array substrate according to claim 1, wherein, during the process of utilizing the first mask to pattern the first metal layer for forming the gate electrodes, the first metal layer is etched by using a mixed solution of nitric acid, phosphoric acid and acetic acid.

16. The method for manufacturing the TFT array substrate according to claim 1, wherein, during the process of utilizing the multi tone mask to pattern the transparent and electrically conductive layer and the second metal layer for forming the source electrodes and the drain electrodes, the second metal layer is etched by using a mixed solution of nitric acid, phosphoric acid and acetic acid, and the transparent and electrically conductive layer is etched by a reactive ion etching (RIE), and during the process of utilizing the multi tone mask to pattern the transparent and electrically conductive layer for forming the pixel electrodes and the common electrodes, the transparent and electrically conductive layer is etched by RIE.

17. A TFT array substrate, comprising:
a substrate;
a plurality of TFTs disposed on the substrate, wherein each of the TFTs comprises a gate electrode, a gate insulating layer, a semiconductor layer, a source electrode and a drain electrode, and the semiconductor layer, the source electrode and the drain electrode are formed on the substrate in sequence, and the source electrode and the drain electrode are formed by patterning a transparent and electrically conductive layer and a metal layer;
a plurality of pixel electrodes formed on the gate insulating layer and connected to the drain electrodes of the TFTs; and
a plurality of common electrodes formed on the gate insulating layer, wherein the pixel electrodes and the common electrodes are arranged in an alternating manner.

18. The TFT array substrate according to claim 17, wherein the first metal layer is a combination of a first aluminum metal layer and a first molybdenum metal layer, and the second metal layer is a combination of a second molybdenum metal layer, a second aluminum metal layer and a third molybdenum metal layer.
